(19) United States
(12) Patent Application Publication
(10) Pub. No.: US 2004/0104110 A1
(43) Pub. Date: Jun. 3, 2004

(54) Topologically tailored sputtering targets

(76) Inventor: Eal H. Lee, Milpitas, CA (US)

Correspondence Address: BINGHAM, MCCUTCHEN LLP, THREE EMBARCADERO, SUITE 1800, SAN FRANCISCO, CA, 94111-4067, US

(21) Appl. No.: 10/672,690

(22) Filed: Sep. 26, 2003

(30) Foreign Application Priority Data
Jun. 17, 2003 (EP) 02723274.3
Feb. 20, 2002 (WO) PCT/US02/06146

(51) Int. Cl. C23C 14/32

(52) U.S. Cl. 204/192.1; 204/298.12; 204/298.13; 204/192.12

(57) ABSTRACT

In a standard target configuration, sputtered atoms distribute in a wide angle producing a non-uniform film and poor step coverage, mainly because the flux of sputtered atoms are not collimated and the center region of the wafer experiences a higher flux of sputtered atoms than the edge of the wafer. Sputtering targets described herein are topologically and morphologically tailored such that sputtered atoms impinge directly toward a wafer in a narrow cosine distribution. In effect, the target is designed with a built-in collimator. The desired morphology and topography can be accomplished by micro (e.g., parabolic dimples) and/or macro scale (e.g., wafer contour, circular wave contour) modification of the target geometry and topography.

This application claims the benefit of PCT application number PCT/US02/06146 filed on Feb. 20, 2002 and European application number 02723274.3 filed on Jun. 17, 2003, incorporated herein by reference in its entirety.

### FIELD OF THE INVENTION

The field of the invention is sputtering targets for physical vapor deposition (PVD).

### BACKGROUND

Electronic and semiconductor components are used in ever increasing numbers of consumer and commercial electronic products, communications products and data-exchange products. Examples of some of these consumer and commercial products are televisions, computers, cell phones, pagers, palm-type organizers, portable radios, car stereos, or remote controls. As the demand for these consumer and commercial electronics increases, there is also a demand for those same products to become smaller and more portable for the consumers and businesses.

As a result of the size decrease in these products, the components that comprise the products must also become smaller and/or thinner. Examples of some of those components that need to be reduced in size or scaled down are microelectronic chip interconnections, semiconductor chip components, resistors, capacitors, printed circuit or wiring boards, wiring, keyboards, touch pads, and chip packaging.

When electronic and semiconductor components are reduced in size or scaled down, any defects that are present in the larger components are going to be exaggerated in the scaled down components. Thus, the defects that are present or could be present in the larger component should be identified and corrected, if possible, before the component is scaled down for the smaller electronic products.

In order to identify and correct defects in electronic, semiconductor and communications components, the components, the materials used and the manufacturing processes for making those components should be broken down and analyzed. Electronic, semiconductor and communication/data-exchange components are composed, in some cases, of layers of materials, such as metals, metal alloys, ceramics, inorganic materials, polymers, or organometallic materials. The layers of materials are often thin (on the order of less than a few tens of angstroms in thickness). In order to improve on the quality of the layers of materials, the process of forming the layer—such as physical vapor deposition of a metal or other compound—should be evaluated and, if possible, improved.

In a typical physical vapor deposition (PVD) process, a sample or target is bombarded with an energy source such as a plasma, laser or ion beam, until atoms are released into the surrounding atmosphere. The atoms that are released from the sputtering target travel towards the surface of a substrate (typically a silicon wafer) and coat the surface forming a thin film or layer of a material. A standard PVD target configuration tends to produce “center-thick” and “edge-thin” deposits because of a cosine distribution of sputtered atoms. (see Prior Art FIG. 1 and U.S. Pat. No. 5,302,266; U.S. Pat. No. 5,225,393; U.S. Pat. No. 4,026,787; and U.S. Pat. No. 3,884,787). Prior Art FIG. 1 shows a conventional PVD arrangement comprising a sputtering target 10 and a wafer or substrate 20. Atoms are released from the sputtering target 10 and travel on an ion/atom path 30 towards the wafer or substrate 20, where they are deposited in a layer.

Several methods and devices have been suggested to correct a large cosine distribution of sputtered atoms in order to deposit a more uniform metal film. One popular method is to physically place or mount a separate collimator or similar type of aperture between the target and the surface, wafer or substrate. (see Prior Art FIG. 2 and U.S. Pat. No. 5,409,587; U.S. Pat. No. 4,923,585) The collimator is designed to reduce the number of metal atoms hitting the substrate or wafer at large angles, while allowing the metal atoms traveling at smaller angles to pass and deposit on the substrate or wafer, which reduces the buildup on the top of the contact and via, and increases the fraction of atoms that land in the bottom and side wall of the contact or via. Prior Art FIG. 2 shows a conventional PVD arrangement comprising a sputtering target 110, a wafer or substrate 120 and a separate collimator 140. Atoms are released from the sputtering target 110 and travel on an ion/atom path 130 towards the wafer or substrate 120, where the atoms are “screened” by the collimator 140. The atoms that pass the collimator 140 are deposited in a layer on the wafer or substrate 120.

Adding a collimator to the target/substrate assembly, however, significantly increases the expense of a target material and also reduces the target life because atoms traveling at high angles are deposited on the collimator instead of the wafer, and thus, are effectively wasted in the process. Also, adding a collimator requires a larger target-to-wafer spacing than that in the standard (collimator-free) process to accommodate the collimator and to prevent a collimator-shaped pattern formation on the wafer. Moreover, the stray atoms deposited on the collimator tend to choke up the collimator, further decreasing the efficiency of deposition and often causing an undesirable particulate formation when the deposits flake off of the collimator surface.

Another method of attempting to create more uniform deposits is to ionize the sputtered atoms by applying radio-frequency (RF) power to the plasma (ionized metal plasma (IMP) process). (see U.S. Pat. No. 6,296,743) In this process, all exposed surfaces in the RF plasma develop a negative potential with respect to the plasma because of the higher mobility of the electrons relative to the heavier ions. Thus the metal ions are attracted to the wafer surface by the direct current (DC) self bias even without a pedestal or surface bias. These perpendicularly-traveling metal ions usually hit the bottom of the contacts or vias and improve the bottom and side wall coverage. However, the RF plasma apparatus and operating conditions contribute to a substantial increase in system cost and operational complexity. RF plasma configurations have also been combined with magnets to further adjust the path of atoms traveling toward the substrate or wafer, however, these methods can be cost prohibitive and difficult to arrange and monitor. (see U.S. Pat. No. 6,153,061; U.S. Pat. No. 6,326,627; U.S. Pat. No. 6,117,281; U.S. Pat. No. 5,865,969; U.S. Pat. No. 5,766,426; U.S. Pat. No. 5,417,833; U.S. Pat. No. 5,188,717; U.S. Pat. No. 5,135,819; U.S. Pat. No. 5,126,029; U.S. Pat. No. 5,106,821; U.S. Pat. No. 4,500,409; U.S. Pat. No. 4,414,086; U.S. Pat. No. 4,610;770; and U.S. Pat. No. 4,629,548)

Other methods of improving the sputtering process to produce more uniform films have been developed. For example, Honeywell Electronic Materials™ (HEM) demonstrated that sputtering characteristics of a target could be improved substantially by using a superfine grain size target, which are produced by the patented technology of the Equal-Channel Angular Extrusion (ECAE®) process (U.S. Pat. Nos. 5,590,389; 5,780,755; and 5,809,393). The demonstrated benefits include low arcing, long target life, high device yield, better film uniformity, and low particulate. Honeywell Electronic Materials™ has also demonstrated that the crystallographic texture of the target can be modified—in a non-pattern-forming fashion—to provide collimating benefits. (see U.S. Pat. No. 5,993,621 and U.S. Pat. No. 6,302,977). The self-ionization plasma (SIP) has also been reviewed as a sputtering process that could produce more uniform films. This process utilizes low pressure and high power to promote self-ionization of sputtered target atoms. SIP requires an extended target-to-substrate spacing, which creates a long ion path. The long ion path improves a directionality of ion flux but again reduces the target yield. The extended ion path length results in further increased cosine loss and making it quite inefficient in target usage. Additional methods include mechanically adjusting the wafer or substrate during the sputtering process (U.S. Pat. No. 6,224,718); masking part of the surface (U.S. Pat. No. 5,894,058; U.S. Pat. Nos. 5,942,356; 6,242,138); chemically treating the vapor between the target and the surface or wafer (U.S. Pat. No. 6,057,238; U.S. Pat. No. 6,107,688; U.S. Pat. No. 4,793,908; U.S. Pat. No. 6,222,271; and U.S. Pat. No. 6,194,783); and Laser sputtering and excitation of the atoms (U.S. Pat. No. 5,382,457). With the exception of the ECAE process, the other methods require additional mechanical or chemical components to be added to the basic PVD process and apparatus, which can increase the cost and complexity of the apparatus and process.

To this end, it would be desirable to produce a PVD target and target/wafer assembly that a) takes advantage of the advantageous minimum depth arrangement; b) keeps the overall cost of the process relatively low in relation to a traditional PVD process; and c) allows the instrumentation and apparatus to remain simple relative to a traditional PVD process.

### SUMMARY OF THE INVENTION

The aging behavior of a standard target suggests that the direction of sputtered atoms can be controlled by modifying the surface morphology or topology of a target. In a standard target configuration, sputtered atoms distribute in a wide angle producing a non-uniform film, mainly because the center region of the wafer experiences a higher flux of sputtered atoms than the edge of the wafer.

Sputtering targets described herein are topologically and morphologically tailored such that sputtered atoms impinge directly toward a wafer in a narrow cosine distribution. In effect, the target is designed with a built-in collimator. The desired morphology and topography can be accomplished by micro (e.g., parabolic dimples) and/or macro scale (e.g., target surface contour) modification of the target geometry and topography.

Self-collimating sputtering targets may comprise any suitable shape and size depending on the application and instrumentation used in the PVD process and any component capable of being sputtered in a sputtering chamber. Sputtering targets described herein also comprise a surface material and a core material, wherein the surface material is coupled to the core material. The surface material and core material may generally comprise the same elemental makeup or chemical composition/component, or the elemental makeup and chemical composition of the surface material may be altered or modified to be different than that of the core material. Also, a backing plate may be coupled to the core material to provide additional support to the sputtering target and also to provide a mounting apparatus for the sputtering target.

The surface material is that portion of the target that is exposed to the energy source at any measurable point in time and is also that part of the overall target material that is intended to produce atoms that are desirable as a surface coating. Further, the surface material is that part of the sputtering target that comprises at least two intentionally-formed indentations that form a collimating topography or morphology.

The self-collimating sputtering target is formed by a) providing a core material; b) providing a surface material; c) coupling the core material to the surface material to form a sputtering target; and d) forming at least two intentional indentations, wherein the indentations form a collimating topography.

A uniform film or layer is formed on a surface of a component or in order to form a component by: a) providing a self-collimating sputtering target; b) providing a surface; c) placing the surface at a distance from the self-collimating sputtering target; d) bombarding the self-collimating sputtering target with an energy source to form at least one atom; and e) coating the surface with the at least one atom.

Sputtering targets described herein can be incorporated into any process or production design that produces, builds or otherwise modifies electronic, semiconductor and communication components. Electronic, semiconductor and communication components are generally thought to comprise any layered component that can be utilized in an electronic-based, semiconductor-based or communication-based product. Components described herein comprise semiconductor chips, circuit boards, chip packaging, separator sheets, dielectric components of circuit boards, printed-wiring boards, touch pads, wave guides, fiber optic and photon-transport and acoustic-wave-transport components, any materials made u sing or incorporating a dual damascene process, and other components of circuit boards, such as capacitors, inductors, and resistors.

### BRIEF DESCRIPTION OF THE FIGURES

Prior Art FIG. 1 shows a conventional PVD target/surface arrangement.

Prior Art FIG. 2 shows a conventional PVD target/surface arrangement with a separate collimator added to the arrangement.

FIG. 3 graphically shows an embodiment of the present invention.

FIG. 4 graphically shows several embodiments of the present invention.

FIG. 5 shows a contemplated method of forming a self-collimating sputtering target.

FIG. 6 shows a contemplated method of forming a uniform film on a surface.

### DETAILED DESCRIPTION

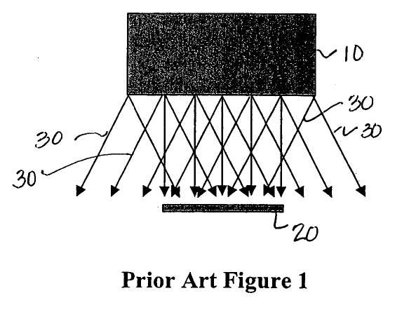

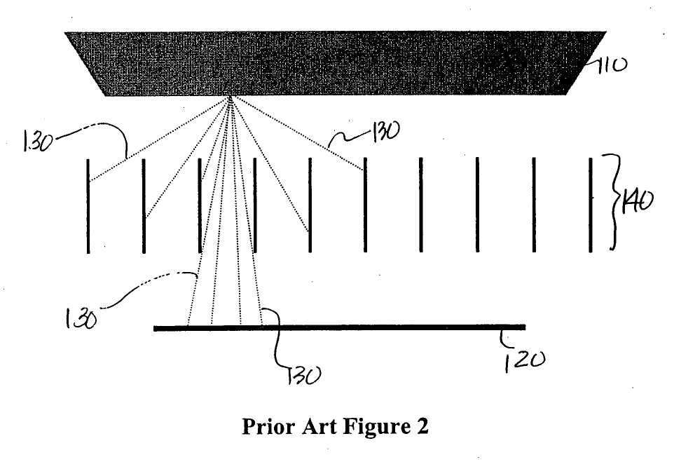

The aging behavior of a target suggests that the direction of sputtered atoms can be controlled by modifying the surface morphology or topology of a target. In a standard target configuration, sputtered atoms distribute in a wide angle producing a non-uniform film, mainly because the center region of the wafer experiences a higher flux of sputtered atoms than the edge of the wafer, as illustrated in Prior Art FIG. 1. The direction of sputtered atoms can now be controlled by modifying the surface morphology and topography of a target. Specifically, the surface morphology and topography of a target can be tailored such that sputtered atoms impinge directly toward a wafer in a narrow cosine distribution as illustrated in FIG. 3.

FIG. 3 shows a contemplated PVD arrangement comprising a sputtering target 210, and a wafer or substrate 220. The sputtering target 210 comprises a surface material 260 and a core material 270. The surface material 260 comprises intentionally-formed indentations (in this case microdimples 250). These intentionally-formed indentations are also formed as a pattern on the sputtering target. As used herein, the term “pattern” means any formation of intentionally-formed indentations that is repeating, arranged or both repeating and arranged. Atoms are “pre-screened” by the microdimples 250 that act as a “built-in collimator”, in that they are bombarded in such a way that they are manipulated at the time of release to travel a certain ion/atom path 230. The atoms are then released from the sputtering target 210 and travel on an ion path 230 towards the wafer or substrate 220. The desired morphology and topography can be accomplished by micro (e.g., parabolic dimples) and/or macro scale (e.g., target surface contour) modification of the target geometry and topography. A backing plate may be coupled to the core material to provide additional support to the sputtering target and also to provide a mounting apparatus for the sputtering target.

Sputtering targets contemplated herein comprise any suitable shape and size depending on the application and instrumentation used in the PVD process. Sputtering targets contemplated herein also comprise a surface material 260 and a core material 270, wherein the surface material 260 is coupled to the core material 270. As used herein, the term “coupled” means a physical attachment of two parts of matter or components (adhesive, attachment interfacing material) or a physical and/or chemical attraction between two parts of matter or components, including bond forces such as covalent and ionic bonding, and non-bond forces such as Van der Waals, electrostatic, coulombic, hydrogen bonding and/or magnetic attraction. The surface material 260 and core material 270 may generally comprise the same elemental makeup or chemical composition/component, or the elemental makeup and chemical composition of the surface material 260 may be altered or modified to be different than that of the core material 270. In most embodiments, the surface material 260 and the core material 270 comprise the same elemental makeup and chemical composition. However, in embodiments where it may be important to detect when the target's useful life has ended or where it is important to deposit a mixed layer of materials, the surface material 260 and the core material 270 may be tailored to comprise a different elemental makeup or chemical composition.

The surface material 260 is that portion of the target 210 that is exposed to the energy source at any measurable point in time and is also that part of the overall target material that is intended to produce atoms that are desirable as a surface coating. Further, the surface material 260 is that part of the sputtering target 210 that comprises at least two intentionally-formed indentations that form a collimating topography or morphology. As used herein, the phrase “collimating topography” is that part of the surface material 260 of the sputtering target 210 that directly influences the cosine distribution of atoms in such a way that the cosine atom distribution is measurably narrowed over the atom distribution found where a conventional sputtering target is utilized. In other words, without any external factors, such as magnets, chemical additives or masks, the incorporation of at least two intentionally-formed indentations that form a collimating topography can narrow the conventional cosine distribution of atoms that would normally be produced from a conventional sputtering target, although there may be external factors that are further influencing the sputtered atoms. The difference between a conventional cosine distribution of atoms and a narrowed cosine distribution of atoms can be seen in Prior Art FIG. 1 and FIG. 3, as discussed earlier.

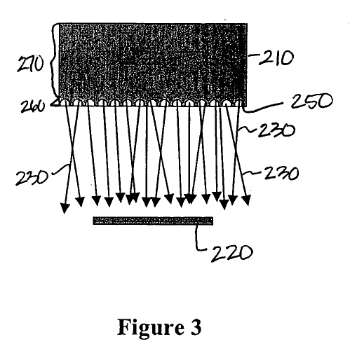

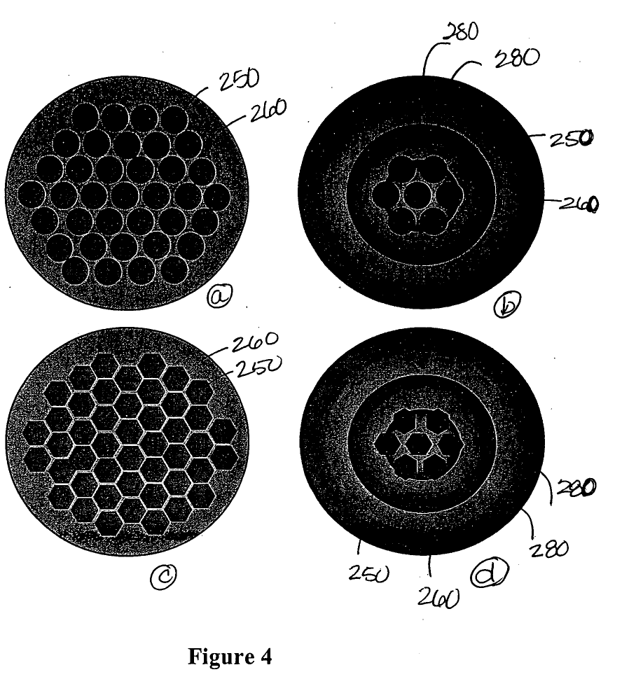

As mentioned, at least two intentionally-formed indentations are formed in the surface material 260 of the sputtering target 210 to create a collimating topography or morphology. Embodiments that comprise relatively large intentionally-formed indentations generally comprise what is referred to as a “macroscale modification”. The phrase “macroscale modification” is used herein to mean tailoring the target surface in a circular wave contour to compensate uneven erosion of a target due to the rotating magnets in a magnetron sputtering system. A macroscale modification 280 (as shown in FIG. 4) in most embodiments will generally comprise relatively large and intentionally-formed indentations in the sputtering target 210, such indentation might resemble a convex or concave lens or a cone. Embodiments that comprise more than two relatively small intentionally-formed indentations generally comprise what are referred to as “microdimples” 250. The term “microdimples”, as used herein, means those indentations that comprise an opening that has a closed loop shape, wherein the shapes include a circle (circular), a hexagon (hexagonal), a triangle (triangular), a square, an oval and other curved or straight-edged closed loops, and will have an aspect ratio greater than 1:1. FIG. 3 shows a cross-section view of microdimples in a sputtering target. FIG. 4 shows a top view of microdimples 250 and macroscale modifications 280 in a sputtering target 210. FIG. 4 also shows the closed loop shape concept in sputtering targets that comprise microdimples 250. It is further contemplated that a sputtering target may comprise both a macroscale modification 280 and microdimples 250. Sputtering targets 4(b) and 4(d) in FIG. 4 are targets that comprise both macroscale modifications 280 and microdimples 250.

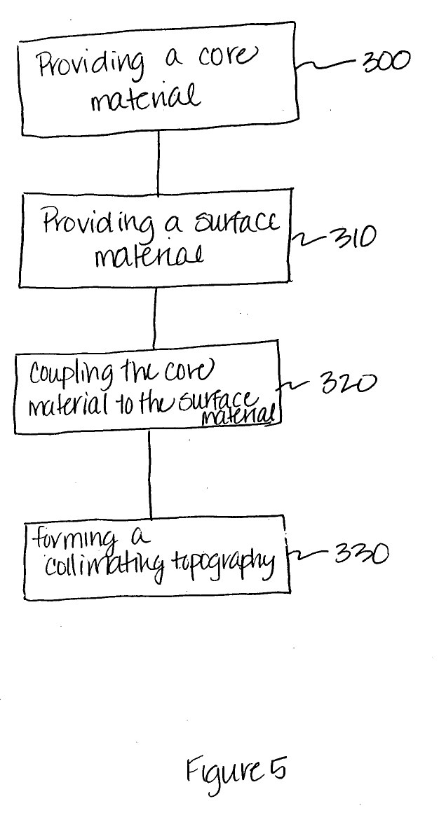

Macroscale modifications 280 and microdimples 2 50 may either be formed through a molding process when the target is originally produced or by some physical or mechanical machining, chemical and/or etching/removal process. It is further contemplated that the macroscale modifications 280 could be molded into the target 210 when the target 210 is initially formed and the microdimples 250 are etched into the target 210 after it is initially formed, or vice versa. More specifically, as shown i n FIG. 5, the self-collimating sputtering target 210 is formed by a) providing a core material 270 (300); b) providing a surface material 260 (310); c) coupling the core material 270 to the surface material 260 to form a sputtering target 210 (320); and d) forming at least two intentional indentations, wherein the indentations form a collimating topography (330).

The core material 270 is designed to provide support for the surface material 260 and to possibly provide additional atoms in a sputtering process or information as to when a target's useful life has ended. For example, in a situation where the core material 270 comprises a material different from that of the original surface material 260, and a quality control device detects the presence of core material atoms in the space between the target 210 and the wafer 220, the target 210 may need to be removed and retooled or discarded altogether because the chemical integrity and elemental purity of the metal coating could be compromised by depositing undesirable materials on the existing surface/wafer layer. The core material 270 is also that portion of a sputtering target 210 that does not comprise macroscale modifications 280 or microdimples 250. In other words, the core material 270 is generally uniform in structure and shape.

Sputtering targets 210 may generally comprise any material that can be a) reliably formed into a sputtering target; b) sputtered from the target when bombarded by an energy source; and c) suitable for forming a final or precursor layer on a wafer or surface. Materials that are contemplated to make suitable sputtering targets 210 are metals, metal alloys, conductive polymers, conductive composite materials, conductive monomers, dielectric materials, hardmask materials and any other suitable sputtering material. As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Preferred metals include titanium, silicon, cobalt, copper, nickel, iron, zinc, vanadium, zirconium, aluminum and aluminum-based materials, tantalum, niobium, tin, chromium, platinum, palladium, gold, silver, tungsten, molybdenum, cerium, promethium, thorium or a combination thereof. More preferred metals include copper, aluminum, tungsten, titanium, cobalt, tantalum, magnesium, lithium, silicon, manganese, iron or a combination thereof. Most preferred metals include copper, aluminum and aluminum-based materials, tungsten, titanium, zirconium, cobalt, tantalum, niobium or a combination thereof. Examples of contemplated and preferred materials, include aluminum and copper for superfine grained aluminum and copper sputtering targets; aluminum, copper, cobalt, tantalum, zirconium, and titanium for use in 300 mm sputtering targets; and aluminum for use in aluminum sputtering targets that deposit a thin, high conformal “seed” layer of aluminum onto surface layers. It should be understood that the phrase “and combinations thereof” is herein used to mean that there may be metal impurities in some of the sputtering targets, such as a copper sputtering target with chromium and aluminum impurities, or there may be an intentional combination of metals and other materials that make up the sputtering target, such as those targets comprising alloys, borides, carbides, fluorides, nitrides, silicides, oxides and others.

The term “metal” also includes alloys, metal/metal composites, metal ceramic composites, metal polymer composites, as well as other metal composites. Alloys contemplated herein comprise gold, antimony, arsenic, boron, copper, germanium, nickel, indium, palladium, phosphorus, silicon, cobalt, vanadium, iron, hafnium, titanium, iridium, zirconium, tungsten, silver, platinum, tantalum, tin, zinc, lithium, manganese, rhenium, and/or rhodium. Specific alloys include gold antimony, gold arsenic, gold boron, gold copper, gold germanium, gold nickel, gold nickel indium, gold palladium, gold phosphorus, gold silicon, gold silver platinum, gold tantalum, gold tin, gold zinc, palladium lithium, palladium manganese, palladium nickel, platinum palladium, palladium rhenium, platinum rhodium, silver arsenic, silver copper, silver gallium, silver gold, silver palladium, silver titanium, titanium zirconium, aluminum copper, aluminum silicon, aluminum silicon copper, aluminum titanium, chromium copper, chromium manganese palladium, chromium manganese platinum, chromium molybdenum, chromium ruthenium, cobalt platinum, cobalt zirconium niobium, cobalt zirconium rhodium, cobalt zirconium tantalum, copper nickel, iron aluminum, iron rhodium, iron tantalum, chromium silicon oxide, chromium vanadium, cobalt chromium, cobalt chromium nickel, cobalt chromium platinum, cobalt chromium tantalum, cobalt chromium tantalum platinum, cobalt iron, cobalt iron boron, cobalt iron chromium, cobalt iron zirconium, cobalt nickel, cobalt nickel chromium, cobalt nickel iron, cobalt nickel hafnium, cobalt niobium hafnium, cobalt niobium iron, cobalt niobium titanium, iron tantalum chromium, manganese iridium, manganese palladium platinum, manganese platinum, manganese rhodium, manganese ruthenium, nickel chromium, nickel chromium silicon, nickel cobalt iron, nickel iron, nickel iron chromium, nickel iron rhodium, nickel iron zirconium, nickel manganese, nickel vanadium, tungsten titanium and/or combinations thereof.

As far as other materials that are contemplated herein for sputtering targets 210, the following combinations are considered examples of contemplated sputtering targets 210 (although the list is not exhaustive): chromium boride, lanthanum boride, molybdenum boride, niobium boride, tantalum boride, titanium boride, tungsten boride, vanadium boride, zirconium boride, boron carbide, chromium carbide, molybdenum carbide, niobium carbide, silicon carbide, tantalum carbide, titanium carbide, tungsten carbide, vanadium carbide, zirconium carbide, aluminum fluoride, barium fluoride, calcium fluoride, cerium fluoride, cryolite, lithium fluoride, magnesium fluoride, potassium fluoride, rare earth fluorides, sodium fluoride, aluminum nitride, boron nitride, niobium nitride, silicon nitride, tantalum nitride, titanium nitride, vanadium nitride, zirconium nitride, chromium silicide, molybdenum silicide, niobium silicide, tantalum silicide, titanium silicide, tungsten silicide, vanadium silicide, zirconium silicide, aluminum oxide, antimony oxide, barium oxide, barium titanate, bismuth oxide, bismuth titanate, barium strontium titanate, chromium oxide, copper oxide, hafnium oxide, magnesium oxide, molybdenum oxide, niobium pentoxide, rare earth oxides, silicon dioxide, silicon monoxide, strontium oxide, strontium titanate, tantalum pentoxide, tin oxide, indium oxide, indium tin oxide, lanthanum aluminate, lanthanum oxide, lead titanate, lead zirconate, lead zirconate-titanate, titanium aluminide, lithium niobate, titanium oxide, tungsten oxide, yttrium oxide, zinc oxide, zirconium oxide, bismuth telluride, cadmium selenide, cadmium telluride, lead selenide, lead sulfide, lead telluride, molybdenum selenide, molybdenum sulfide, zinc selenide, zinc sulfide, zinc telluride and/or combinations thereof.

Thin layers or films produced by the sputtering of atoms from targets discussed herein can be formed on any number or consistency of layers, including other metal layers, substrate layers 220 dielectric layers, hardmask or etchstop layers, photolithographic layers, anti-reflective layers, etc. In some preferred embodiments, the dielectric layer may comprise dielectric materials contemplated, produced or disclosed by Honeywell International, Inc. including, but not limited to: a) FLARE (poly(arylene ether)), such as those compounds disclosed in issued patents U.S. Pat. No. 5,959,157, U.S. Pat. No. 5,986,045, U.S. Pat. No. 6,124,421, U.S. Pat. No. 6,156,812, U.S. Pat. No. 6,172,128, U.S. Pat. No. 6,171,687, U.S. Pat. No. 6,214,746, and pending application Ser. Nos. 09/197478, 09/538276, 09/544504, 09/741634, 09/651396, 09/545058, 09/587851, 09/618945, 09/619237, 09/792606, b) adamantane-based materials, such as those shown in pending application 09/545058 ; Serial PCT/US00/22204 filed Oct. 17, 2001; PCT/US01/50182 filed Dec. 31, 2001; U.S. Pat. No. 60/345374 filed Dec. 31, 2001; Ser. No. 60/347195 filed Jan. 8, 2002; and Ser. No. 60/350187 filed Jan. 15, 2002;, c) commonly assigned U.S. Pat. Nos. 5,115,082; 5,986,045; and 6,143,855; and commonly assigned International Patent Publications WO 01/29052 published Apr. 26, 2001; and WO 01/29141 published Apr. 26, 2001; and (d) nanoporous silica materials and silica-based compounds, such as those compounds disclosed in issued patents U.S. Pat. No. 6,022,812, U.S. Pat. No. 6,037,275, U.S. Pat. No. 6,042,994, U.S. Pat. No. 6,048,804, U.S. Pat. No. 6,090,448, U.S. Pat. No. 6,126,733, U.S. Pat. No. 6,140,254, U.S. Pat. No. 6,204,202, U.S. Pat. No. 6,208,014, and pending application Ser. Nos. 09/046474, 09/046473, 09/111084, 09/360131, 09/378705, 09/234609,09/379866, 09/141287, 09/379484, 09/392413, 09/549659, 09/488075, 09/566287, and 09/214219 all of which are incorporated by reference herein in their entirety and (e) Honeywell HOSP® organosiloxane.

Wafer or substrate 220 may comprise any desirable substantially solid material. Particularly desirable substrates 220 would comprise films, glass, ceramic, plastic, metal or coated metal, or composite material. In preferred embodiments, the substrate 220 comprises a silicon or germanium arsenide die or wafer surface, a packaging surface such as found in a copper, silver, nickel or gold plated leadframe, a copper surface such as found in a circuit board or package interconnect trace, a via-wall or stiffener interface (“copper” includes considerations of bare copper and its oxides), a polymer-based packaging or board interface such as found in a polyimide-based flex package, lead or other metal alloy solder ball surface, glass and polymers such as polyimides. In more preferred embodiments, the substrate 220 comprises a material common in the packaging and circuit board industries such as silicon, copper, glass, or a polymer.

Substrate layers 220 contemplated herein may also comprise at least two layers of materials. One layer of material comprising the substrate layer 220 may include the substrate materials previously described. Other layers of material comprising the substrate layer 220 may include layers of polymers, monomers, organic compounds, inorganic compounds, organometallic compounds, continuous layers and nanoporous layers.

As used herein, the term “monomer” refers to any chemical compound that is capable of forming a covalent bond with itself or a chemically different compound in a repetitive manner. The repetitive bond formation between monomers may lead to a linear, branched, super-branched, or three-dimensional product. Furthermore, monomers may themselves comprise repetitive building blocks, and when polymerized the polymers formed from such monomers are then termed “blockpolymers”. Monomers may belong to various chemical classes of molecules including organic, organometallic or inorganic molecules. The molecular weight of monomers may vary greatly between about 40 Dalton and 20000 Dalton. However, especially when monomers comprise repetitive building blocks, monomers may have even higher molecular weights. Monomers may also include additional groups, such as groups used for crosslinking.

As used herein, the term “crosslinking” refers to a process in which at least two molecules, or two portions of a long molecule, are joined together by a chemical interaction. Such interactions may occur in many different ways including formation of a covalent bond, formation of hydrogen bonds, hydrophobic, hydrophilic, ionic or electrostatic interaction. Furthermore, molecular interaction may also be characterized by an at least temporary physical connection between a molecule and itself or between two or more molecules.

Contemplated polymers may also comprise a wide range of functional or structural moieties, including aromatic systems, and halogenated groups. Furthermore, appropriate polymers may have many configurations, including a homopolymer, and a heteropolymer. Moreover, alternative polymers may have various forms, such as linear, branched, super-branched, or three-dimensional. The molecular weight of contemplated polymers spans a wide range, typically between 400 Dalton and 400000 Dalton or more.

Examples of contemplated inorganic compounds are silicates, aluminates and compounds containing transition metals. Examples of organic compounds include polyarylene ether, polyimides and polyesters. Examples of contemplated organometallic compounds include poly(dimethylsiloxane), poly(vinylsiloxane) and poly(trifluoropropylsiloxane).

The substrate layer 220 may also comprise a plurality of voids if it is desirable for the material to be nanoporous instead of continuous. Voids are typically spherical, but may alternatively or additionally have any suitable shape, including tubular, lamellar, discoidal, or other shapes. It is also contemplated that voids may have any appropriate diameter. It is further contemplated that at least some of the voids may connect with adjacent voids to create a structure with a significant amount of connected or “open” porosity. The voids preferably have a mean diameter of less than 1 micrometer, and more preferably have a mean diameter of less than 100 nanometers, and still more preferably have a mean diameter of less than 10 nanometers. It is further contemplated that the voids may be uniformly or randomly dispersed within the substrate layer. In a preferred embodiment, the voids are uniformly dispersed within the substrate layer 220.

Contemplated benefits of producing and using self-collimating or topologically tailored sputtering targets 210 include simplicity of design, low relative cost, a built-in collimator, better step coverage, and longer relative target life, among other benefits.

Applications

Sputtering targets 210 described herein can be incorporated into any process or production design that produces, builds or otherwise modifies electronic, semiconductor and communication/data transfer components. Electronic, semiconductor and communication components as contemplated herein, are generally thought to comprise any layered component that can be utilized in an electronic-based, semiconductor-based or communication-based product. Contemplated components comprise micro chips, circuit boards, chip packaging, separator sheets, dielectric components of circuit boards, printed-wiring boards, touch pads, wave guides, fiber optic and photon-transport and acoustic-wave-transport components, any materials made using or incorporating a dual damascene process, and other components of circuit boards, such as capacitors, inductors, and resistors.

Electronic-based, semiconductor-based and communications-based/data transfer-based products can be “finished” in the sense that they are ready to be used in industry or by other consumers. Examples of finished consumer products are a television, a computer, a cell phone, a pager, a palm-type organizer, a portable radio, a car stereo, and a remote control. Also contemplated are “intermediate” products such as circuit boards, chip packaging, and keyboards that are potentially utilized in finished products.

Electronic, semiconductor and communication/data transfer products may also comprise a prototype component, at any stage of development from conceptual model to final scale-up mock-up. A prototype may or may not contain all of the actual components intended in a finished product, and a prototype may have some components that are constructed out of composite material in order to negate their initial effects on other components while being initially tested.

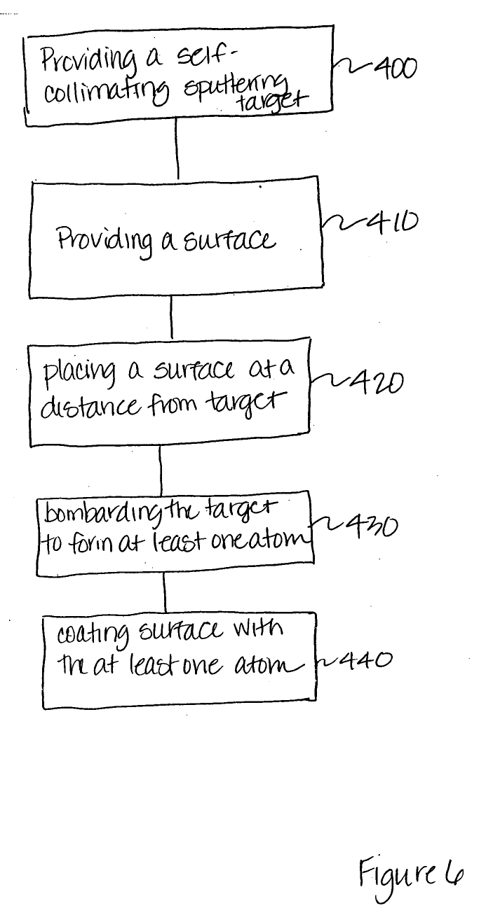

A method of forming a uniform film or layer on a surface of a component or in order to form a component comprises: a) providing a self-collimating sputtering target 400; b) providing a surface 410; c) placing the surface at a distance from the self-collimating sputtering target 420; d) bombarding the self-collimating sputtering target with an energy source to form at least one atom 430; and e) coating the surface with the at least one atom 440, as shown in FIG. 6. The self-collimating sputtering target comprises the sputtering target 210 described herein that further comprises a surface material 260 and a core material 270, wherein the surface material 260 comprises at least two indentations that form a collimating topography. The surface provided is contemplated to be any suitable surface, as discussed herein, including a wafer, substrate, dielectric material, hardmask layer, other metal, metal alloy or metal composite layer, antireflective layer or any other suitable layered material. The distance between the self-collimating sputtering target 210 and the surface 220 is contemplated herein to comprise any suitable distance already utilized in conventional PVD experimental arrangements. The coating, layer or film that is produced on the surface may also be any suitable or desirable thickness—ranging from one atom or molecule thick (less than 1 nanometer) to millimeters in thickness.

Thus, specific embodiments and applications of topologically modified sputtering targets have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

I claim:

1. A sputtering target, comprising:
a core material; and
a surface material coupled to the core material, wherein the surface material comprises at least two indentations that form a collimating topography.

2. The sputtering target of claim 1, wherein the core material and the surface material comprise the same chemical component.

3. The sputtering target of claim 2, wherein the chemical component comprises copper, aluminum, tungsten, titanium, zirconium, cobalt, aluminide, tantalum, magnesium, lithium, silicon, manganese, iron or any combination thereof.

4. The sputtering target of claim 3, wherein the component comprises copper, aluminum, tungsten, titanium, zirconium, cobalt, tantalum, aluminide or a combination thereof.

5. The sputtering target of claim 1, wherein the, at least two indentations comprises a macroscale modification.

6. The sputtering target of claim 5, wherein the macroscale modification comprises a circular wave contour.

7. The sputtering target of claim 1, wherein the at least two indentations comprises at least one microdimple.

8. The sputtering target of claim 7, wherein the at least one microdimple comprises a circular closed loop opening.

9. The sputtering target of claim 7, wherein the at least one microdimple comprises a hexagonal closed loop opening.

10. The sputtering target of claim 1, wherein the at least two indentations comprises a macroscale modification and at least one microdimple.

11. A method of forming a self-collimating sputtering target, comprising:
providing a core material;
providing a surface material;
coupling the core material to the surface material to form a sputtering target; and
forming at least two intentional indentations in the surface material, wherein the indentations form a collimating topography.

12. The method of claim 11, wherein providing the core material and providing the surface material comprise providing the same chemical component.

13. The method of claim 12, wherein the chemical component comprises copper, aluminum, tungsten, titanium, cobalt, aluminide, tantalum, magnesium, lithium, silicon, manganese, iron or any combination thereof.

14. The method of claim 13, wherein the component comprises copper, aluminum, tungsten, titanium, cobalt, tantalum, aluminide or a combination thereof.

15. The method of claim 11, wherein forming at least two intentional indentations in the surface material comprises forming a macroscale modification.

16. The method of claim 11, wherein forming at least two intentional indentations in the surface material comprises forming a circular wave contour.

17. The method of claim 11, wherein forming at least two intentional indentations in the surface material comprises forming at least one microdimple.

18. The method of claim 17, wherein forming the at least one microdimple comprises forming a circular closed loop opening.

19. The method of claim 17, wherein forming the at least one microdimple comprises forming a hexagonal closed loop opening.

20. The method of claim 11, wherein forming at least two intentional indentations in the surface material comprises forming a macroscale modification and at least one microdimple.

21. A method of forming a uniform film on a surface, comprising:
providing a self-collimating sputtering target;
providing a surface;
placing the surface at a distance from the self-collimating sputtering target;
bombarding the self-collimating sputtering target with an energy source to form at least one atom; and
coating the surface with the at least one atom.

22. A film formed from the sputtering target of claim 11.

23. A film formed by the method of claim 21.

24. A component formed by the sputtering target of claim 11.

25. A component incorporating a film formed by the method of claim 21.

26. A capacitor formed by the sputtering target of claim 11.

27. A capacitor incorporating a film formed by the method of claim 21.
